(19) United States
(12) Patent Application Publication
(10) Pub. No.: US 2022/0055891 A1
(43) Pub. Date: Feb. 24, 2022

(54) PHASE CHANGE MICRO SHUTTER ARRAY GRID AND METHOD

(71) Applicant: U.S. Army Combat Capabilities Development Command, Army Research Laboratory, Adelphi, MD (US)

(72) Inventors: Cory R. Knick, Alexandria, VA (US); Christopher J. Morris, Silver Spring, MD (US); Gabriel L. Smith, Ellicott City, MD (US)

(21) Appl. No.: 16/998,458

(22) Filed: Aug. 20, 2020

(51) Int. Cl. B81B 3/00; B81B 7/04

(52) U.S. Cl. CPC B81B 3/0081; B81B 2203/0118; B81B 3/0083; B81B 7/04

(57) ABSTRACT

A microelectromechanical system (MEMS) actuator device includes a substrate; a shape memory alloy over the substrate; and a reflective coating on the shape memory alloy. The shape memory alloy and the reflective coating form a bi-layer cantilever beam having a first end anchored to the substrate, and a second end released from the substrate. The second end of the cantilever beam articulates between a deflection configuration away from the substrate and a non-deflection configuration towards the substrate based on a thermal phase change in the shape memory alloy.

### GOVERNMENT INTEREST

The embodiments herein may be manufactured, used, and/or licensed by or for the United States Government without the payment of royalties thereon.

### BACKGROUND

### Technical Field

The embodiments herein generally relate to phase change materials, and more particularly to microelectromechanical systems (MEMS) actuated using phase change materials.

### Description of the Related Art

Shape memory alloys (SMAs) are a class of functional materials characterized by the ability to ‘remember’ their original form after thermal-mechanical deformation at a high stress level (over 500 MPa) and large recoverable strains (up to 10%). Additionally, the work output (per unit volume) for SMAs is the highest among all smart material actuators (˜10⁷ J m⁻³). SMA applications are found in aerospace, automobiles, robotics, MEMS, biomedical tools. MEMS/NEMS devices are a multi-billion dollar, worldwide market that can benefit from technological development of miniaturized functional, or ‘smart’, materials like SMAs. Due to their high work output (˜10⁷ J m⁻³), NiTi alloy is one of the most well researched and most promising classes of SMA. While SMAs like NiTi have been studied extensively in larger scale devices, their applications have been limited due to low frequency response, typically on the order of 100 Hz or less. However, with miniaturization in applications such as MEMS/NEMS devices comes the promise of overcoming the inherently slow thermal response times due to smaller thermal masses and larger surface area-to-volume ratios.

NiTi has become one of the most widely used SMAs due to its exceptional physical and mechanical properties exhibited through the shape memory effect (SME), including large recoverable strains. The basis for SME in NiTi is the switching between two different crystallographic phases, namely the high temperature phase known as austenite (or) the parent phase, and the low temperature phase known as martensite. The crystal structure of the austenite is a CsCl type B2 cubic structure and the low temperature martensite phase is a complex monoclinic crystal structure (B19′). The martensitic transformation is a diffusionless solid-state phase transformation. During the martensitic transformation, metal atoms move cooperatively in the matrix under shear stresses, resulting in a new phase formed from the parent phase. To accommodate the internal stresses caused by the transformation to the B19′ phase, the formation of a combination of up to 24 multiple martensitic variants is possible, resulting in a twinned martensite crystal form, also known as self-accommodated martensite. This results in large displacements that make NiTi thin films desirable for applications in actuators for MEMS/NEMS devices such as SMA microgrippers, micropumps, and various other bi-stable, thermally driven actuators.

The majority of NiTi films are fabricated by RF or DC magnetron sputtering methods, and these films are amorphous, unless the substrates are heated during deposition. NiTi films deposited in this manner exhibit interesting behaviors, such as lowered crystallization temperature and oriented crystallographic structure. However, post deposition annealing at a temperature above 700 K (equivalent to 427° C.) is necessary for the films to crystallize and exhibit the shape memory effects. Alternatively, films can be deposited on heated substrates for in situ crystallization. NiTi film properties can also be tailored through the composition and structure of the sputtered alloy, which is significantly affected by the sputtering conditions (e.g. target power, gas pressure, target to substrate distance, deposition temperature, and substrate bias voltage).

One issue with creating SMA thin film structures is the phase transformation behavior is strongly affected by size reduction. It has been established that this behavior can vanish entirely for films with grain sizes below ˜80 nm. Therefore, SMA films should be at least 100 nm thick to exhibit any measurable shape memory effect. Therefore, it is quite challenging to obtain the desired fast-response SMA due to the increasing challenge of miniaturization of SMA films and actuators. Despite this constraint, numerous bimorph and trimorph actuator devices based on the SME films have been fabricated and characterized. Since then, several studies looking at modeling and characterization of SMA bimorph/trimorph actuators have been proposed.

Some solutions have accounted for the phase dependent frequency shift and static deflection in nanoscale thickness NiTi films, due to the non-linear changes in Young's modulus (i.e. stiffness, rigidity) and residual film stress across the phase transition between martensite and austenite. In other words, these solutions present the theory for using steady state substrate temperature to modulate the resonant frequency of suspended NiTi SMA cantilevers, by exploiting the temperature-dependent mechanical properties of NiTi coated on elastic substrate with resonant frequencies in the hundreds of kHz range. However, a major drawback for SMAs in many applications has been the low frequency response, which is typically on the order of 100 Hz or lower, even in microscale SMA actuators.

Some conventional solutions demonstrate that thin film PZT actuators can be used as variable capacitors and MEMS switches for RF network applications. The PZT actuators offer the advantage of a more or less linear response to applied voltage, but require relatively high voltages (>10 V) to operate, which is not always available in power-constrained electronic environments. Accordingly, a new solution is required to meet the demands of power-constrained electronic environments.

### SUMMARY

In view of the foregoing, an embodiment herein provides a MEMS actuator device comprising a substrate; a shape memory alloy over the substrate; and a reflective coating on the shape memory alloy, wherein the shape memory alloy and the reflective coating form a bi-layer cantilever beam comprising a first end anchored to the substrate, and a second end released from the substrate, and wherein the second end of the cantilever beam articulates between a deflection configuration away from the substrate and a non-deflection configuration towards the substrate based on a thermal phase change in the shape memory alloy.

The second end of the cantilever beam may articulate to the deflection configuration after being in the non-deflection configuration when the shape memory alloy is at a temperature below a phase change temperature of the shape memory alloy. An articulation of the second end of the cantilever beam between the deflection configuration and the non-deflection configuration may comprise a frequency response up to 3,000 Hz. The articulation of the second end of the cantilever beam may consume approximately 1 mW of power. The cantilever beam may be exposed to resistive heating to cause a temperature of the cantilever beam to reach a phase change temperature of the shape memory alloy to cause the second end of the cantilever beam to deflect towards the substrate. The cantilever beam may be exposed to a laser beam to cause a temperature of the cantilever beam to reach a phase change temperature of the shape memory alloy to cause the second end of the cantilever beam to deflect towards the substrate. The articulation of the second end of the cantilever beam towards the substrate does not depend on the wavelength of the laser beam.

Another embodiment provides a micro shutter system comprising a plurality of MEMS actuator devices arranged in a grid and covering a sensor array or an array of sensors, wherein each MEMS actuator device comprises a substrate; a shape memory alloy over the substrate; and a reflective coating on the shape memory alloy, wherein the shape memory alloy and the reflective coating form a cantilever beam, wherein the cantilever beam actuates between a curled configuration away from the substrate and a non-curled configuration towards the substrate when a temperature of the cantilever beam reaches a phase change temperature of the shape memory alloy causing a thermal phase change in the shape memory alloy, and wherein each MEMS actuator device of the plurality of MEMS actuator devices independently actuates in response to being selectively heated. The micro shutter system further comprises a rigid shutter attached to each MEMS actuator device, wherein actuation of the cantilever beam actuates the rigid shutter over the sensor array.

Each MEMS actuator device may comprise a bimorph actuator. The bimorph actuator may comprise a first cantilever beam comprising a first beam first end anchored to the substrate, and a first beam second end released from the substrate; a second cantilever beam parallel to the first cantilever beam, wherein the second cantilever beam comprises a second beam first end anchored to the substrate, and a second beam second end released from the substrate; a lateral beam connecting the first beam second end to the second beam second end; and a gap between the first cantilever beam and the second cantilever beam, wherein a width of the gap is defined by a length of the lateral beam.

The reflective coating may be at least three times thicker than the shape memory alloy. The independent actuation of each MEMS actuator device of the plurality of MEMS actuator devices in response to being selectively heated may result in at least one of the plurality of MEMS actuator devices in the grid being in the curled configuration while remaining ones of the plurality of MEMS actuator devices in the grid being in the non-curled configuration. The rigid shutter may comprise a film that is thermally or electrically biased to be infrared transmissive or infrared reflective. Each MEMS actuator device may comprise a thermal expansion mismatch between the shape memory alloy and the reflective coating. Each rigid shutter in the grid may independently actuate based on corresponding actuation of an attached MEMS actuator device.

Another embodiment provides a method of forming a MEMS actuator device, the method comprising providing a substrate; patterning a shape memory alloy on the substrate; patterning a reflective coating on the shape memory alloy; and creating a bi-layer cantilever beam containing the shape memory alloy and the reflective coating by removing a portion of the substrate from below the shape memory alloy, wherein a first end of the cantilever beam is anchored to the substrate, and a second end of the cantilever beam is released from the substrate, wherein the second end of the cantilever beam curls away from the substrate, and wherein the second end of the cantilever beam is configured to uncurl based on a thermal phase change in the shape memory alloy.

The shape memory alloy may be formed of a NiTi-based alloy. The method may comprise forming a rigid structure containing a variably infrared transmissive material; and operatively connecting the rigid structure to the cantilever beam, wherein the rigid structure is configured to be deflected based on an actuation of the cantilever beam from an uncurled configuration to a curled configuration. The method may comprise coating the rigid structure with an ultra-high absorbance material. The method may comprise electroplating the second end of the cantilever beam to cause the second end to curl away from the substrate in one direction.

These and other aspects of the embodiments herein will be better appreciated and understood when considered in conjunction with the following description and the accompanying drawings. It should be understood, however, that the following descriptions, while indicating exemplary embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a graphical diagram illustrating a stress versus temperature hysteresis loop for 270 nm thick SMA film on Si wafer (5 mTorr deposition pressure), according to an embodiment herein;

FIG. 2A is a schematic diagram illustrating a step of layering a shape memory alloy and photoresist on a substrate for forming a MEMS actuator device, according to an embodiment herein;

FIG. 2B is a schematic diagram illustrating a step of patterning the shape memory alloy for forming a MEMS actuator device, according to an embodiment herein;

FIG. 2C is a schematic diagram illustrating a step of applying and patterning a reflective coating on the shape memory alloy and substrate for forming a MEMS actuator device, according to an embodiment herein;

FIG. 2D is a schematic diagram illustrating a state of deflection/release of a MEMS actuator device, according to an embodiment herein;

FIG. 2E is a schematic diagram illustrating a state of non-deflection/actuation of a MEMS actuator device, according to an embodiment herein;

FIG. 3A is a schematic top down diagram illustrating a MEMS SMA bimorph actuator device, according to an embodiment herein;

FIG. 3B is a schematic cross-sectional diagram illustrating a MEMS SMA bimorph actuator device, according to an embodiment herein;

FIG. 4 is a graphical diagram illustrating a modeled and measured radius of curvature for 50 μm length cantilevers, 5 μm wide of 1 μm SU-8/270 nm NiTi for various SU8 post-bake temperatures, according to an embodiment herein;

FIG. 5A is a schematic diagram illustrating a micro shutter system in a curled configuration, according to an embodiment herein;

FIG. 5B is a schematic diagram illustrating a micro shutter system in an uncurled configuration, according to an embodiment herein;

FIG. 6A is a schematic diagram illustrating a micro shutter system containing an array of MEMS actuator devices and shutters arranged in a grid, according to an embodiment herein;

FIG. 6B is a scanning electron microscope (SEM) image illustrating a micro shutter system containing an array of MEMS actuator devices and shutters arranged in a grid, according to an embodiment herein;

FIG. 6C is a SEM image diagram illustrating a released shutter controlled by MEMS actuator devices, according to an embodiment herein;

FIG. 7 is a schematic top down diagram illustrating a bimorph actuator device, according to an embodiment herein;

FIG. 8 is a graphical diagram illustrating NiTi SMA joule heater displacement versus applied voltage (V) indicating a completely actuated device at 0.5 V, and nonlinear behavior due to SMA phase change between the M-phase and A-phase, according to an embodiment herein;

FIG. 9 is a SEM image illustrating a released SMA actuator curled out of the substrate with ˜100 μm curvature radius, according to an embodiment herein;

FIG. 10 are graphical diagrams illustrating the measured device deflection versus time at 500 Hz, 1.0, 2.0, and 3.0 kHz square wave actuation (1 Vₚₚ) with 50% duty cycle, according to an embodiment herein;

FIG. 11 is a graphical diagram illustrating a COMSOL® software 3D model of SU-8 on a NiTi actuator used for a thermal model and simulated joule heating transient response of the NiTi actuator, according to an embodiment herein;

FIG. 12A is a flow diagram illustrating a method of forming a MEMS actuator device, according to an embodiment herein;

FIG. 12B is a flow diagram illustrating a method of applying a rigid structure to a MEMS actuator device, according to an embodiment herein;

FIG. 12C is a flow diagram illustrating a method of coating a rigid structure, according to an embodiment herein; and

FIG. 12D is a flow diagram illustrating a method of electroplating a cantilever beam, according to an embodiment herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

It will be understood that when an element or layer is referred to as being “on”, “connected to”, or “coupled to” another element or layer, it may be directly on, directly connected to, or directly coupled to the other element or layer, or intervening elements or layers may be present. In contrast, when an element or layer is referred to as being “directly on”, “directly connected to”, or “directly coupled to” another element or layer, there are no intervening elements or layers present. It will be understood that for the purposes of this disclosure, “at least one of X, Y, and Z” may be construed as X only, Y only, Z only, or any combination of two or more items X, Y, and Z (e.g., XYZ, XYY, XZ, ZY, YZ, XX, YY, ZZ, etc.).

The embodiments herein provide a device and fabrication technique for a MEMS shutter array that can be passively actuated with a laser beam. The process includes coating a bare silicon wafer (520 μm thick) with ˜500 nm of Nickel-Titanium alloy (Nitinol). Other material combinations are also feasible. The fabrication could include 3D printing (e.g. Nanoscribe 2 photo polymerization). The device could include any shape memory alloy including metallic and polymeric material. For example, phase change materials which could be used to drive the actuation could include shape memory alloys, Germanium Telluride (GeTe), and vanadium dioxide (VO₂). VO₂ is also electro-chromic, and could be incorporated into the phase change micro shutter (i.e. it could be used to drive mechanical actuation in some parts and variable-transmission infrared (IR) window in other parts). Vanadium dioxide (VO₂) thin films exhibit good IR transmission at lower temperatures and can be thermally or electrically biased towards a more IR reflective above 68-70° C.

In MEMS applications, the higher surface-to-volume ratios have enabled responses to be improved by an order or magnitude or more. By further shrinking the SMA film/device dimensions, the frequency response can be improved even further, as in accordance with the techniques provided by the embodiments herein, which provides a simplified process for fabricating sputtered, thin film SMA MEMS actuators based on nickel-titanium alloy (NiTi or also referred to as NITINOL) that comprises only one photo step to pattern the actuators using a SU-8 photoresist, for example. When heated through its solid-solid phase transition from low-temperature martensite to high-temperature austenite, the NiTi alloy undergoes changes in associated physical properties, such as Young's modulus, resistivity, and surface roughness, that are critical to controlling MEMS performance. For example, these material property changes allow for the design of active or passive microscale sensors and actuators. This process achieves the fabrication of ultrathin films of NiTi with nanoscale thickness, which can be thermally cycled through two stable positions very rapidly, making it an intriguing thermal sensor and actuator material for high frequency applications. Additionally, NiTi can be used as an active thermal switch through resistive (i.e. joule) heating. Experimentally, the embodiments herein show a greatly improved frequency response of up to 3000 Hz with turn on voltages as low as 0.5 V (corresponding to only 1 mW power consumption) for devices exhibiting microns of cantilever tip deflection over millions of cycles, indicating these new SMA MEMS actuators have suitable applications for low voltage switching, modulation and tuning.

The embodiments herein differ from the conventional solutions by thermally driving the actuation by rapidly modulating the NiTi SMA cantilever temperatures and Young's modulus up to several kHz. In order to better engineer miniature devices using SMAs to take advantage of their unique phase change properties, the fabricating techniques provided by the embodiments herein utilize patterning sputtered NiTi thin films. Using this process, ultrathin films are fabricated exhibiting the SME effect, including a desirable SMA film thickness and subsequent actuator performance (e.g. power consumption, response bandwidth, lifetime, and range of motion) using resistive (i.e. joule) heating.

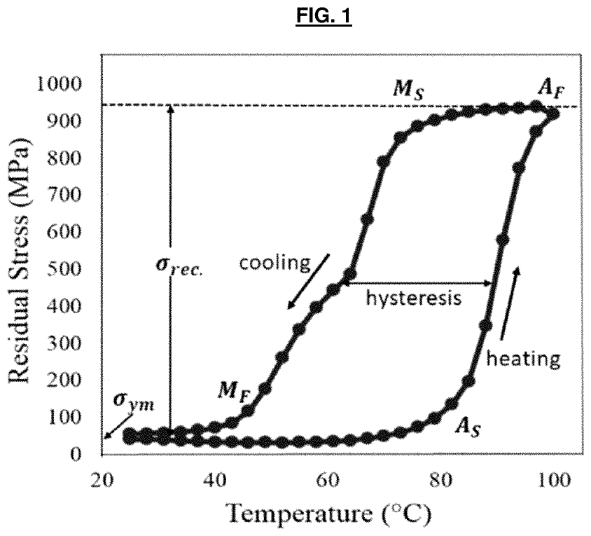

Referring now to the drawings, and more particularly to FIGS. 1 through 12D, where similar reference characters denote corresponding features consistently throughout the figures, there are shown preferred embodiments. In the drawings, the size and relative sizes of components, layers, and regions, etc. may be exaggerated for clarity.

FIG. 1 shows a measured stress versus temperature loop typical for NiTi Martensite-austenite phase change with important definitions defined for recovery stress, thermal hysteresis, as well as the Austenite start, Austenite finish, Martensite start and Martensite finish temperatures. Experimentally, a large reversible stress difference is measured (˜900 MPa) in a 270 nm thick sample deposited at 5 mTorr as shown in FIG. 1. This is most likely due to the phase change between B19′ Martensite and austenite which is accompanied by larger transformation stresses and strains as well as much larger thermal hysteresis. The thermal hysteresis is ˜20° C., As is 75° C., Af is 95° C., Ms is 65° C., and Mf is 40° C. The residual stress is actually quite low, around 50 MPa.

The NiTi is deposited onto a heater wafer (600° C.) for 18 min, at 15 nm min⁻¹ to obtain an in situ crystallized NiTi SMA film of 270±5 nm thickness. This SMA is deposited and characterized similar to what is summarized in Table 1.

TABLE 1
NiTi co-sputter deposition parameters
NiTi deposition in the AJA ATC co-sputter tool

| | |
|---|---|
| NiTi target power (W) | 375 |
| Ti target power (W) | 250 |
| NiTi thickness (nm) | 270 |
| Deposition time (min.) | 18 min @ 15 nm min⁻¹ |
| Dep. Temp. (° C.) | 600 |
| Argon flow (sccm) | 60 |
| Sputter pressure (mTorr) | 5 |

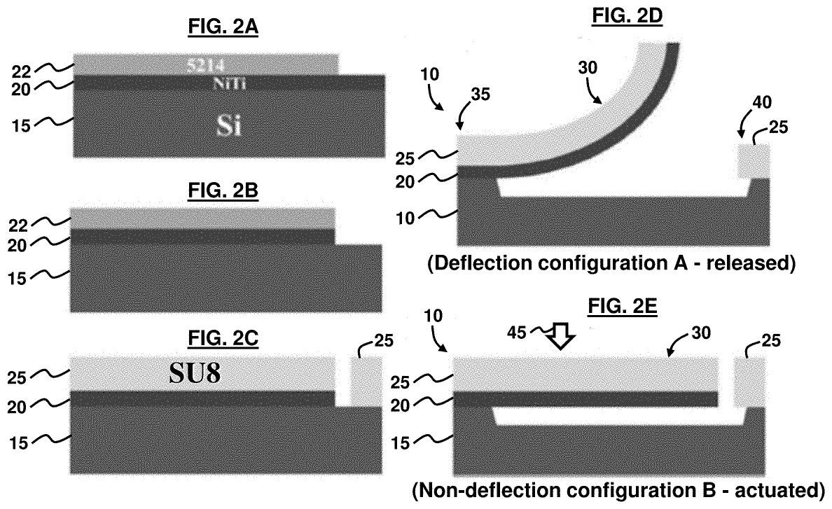

FIGS. 2A through 2C, with reference to FIG. 1, illustrate example schematic diagrams for fabricating a MEMS actuator device 10 comprising a substrate 15, a shape memory alloy 20 over the substrate 15, and a reflective coating 25 on the shape memory alloy 20. In an example, the substrate 15 comprises Si. In an example, the MEMS actuator device 10 may be a joule heater device. In an example, the shape memory alloy 20 comprises NiTi, and the reflective coating 25 comprises SU8. The shape memory alloy 20 and the reflective coating 25 form a bi-layer cantilever beam 30 comprising a first end 35 anchored to the substrate 15, and a second end 40 released from the substrate 15.

As shown in FIGS. 2D and 2E, with reference to FIGS. 1 through 2C, the second end 40 of the cantilever beam 30 articulates between a deflection configuration A away from the substrate 15 and a non-deflection configuration B towards the substrate 15 based on a thermal phase change in the shape memory alloy 20. In an example, the deflection configuration A may be a substantially curled configuration, and the non-deflection configuration B may be a substantially non-curled configuration.

The second end 40 of the cantilever beam 30 may articulate to the deflection configuration A after being in the non-deflection configuration B when the shape memory alloy 20 is at a temperature below a phase change temperature of the shape memory alloy 20. Moreover, according to an example, the articulation of the second end 40 of the cantilever beam 30 between the deflection configuration A and the non-deflection configuration B may comprise a frequency response up to 3,000 Hz. In an example, the articulation of the second end 40 of the cantilever beam 30 may consume approximately 1 mW of power. The cantilever beam 30 may be exposed to resistive heating to cause a temperature of the cantilever beam 30 to reach a phase change temperature of the shape memory alloy 20 to cause the second end 40 of the cantilever beam 30 to deflect towards the substrate 15.

According to an example, the cantilever beam 30 may be exposed to a laser beam 45 to cause a temperature of the cantilever beam 30 to reach a phase change temperature of the shape memory alloy 20 to cause the second end 40 of the cantilever beam 30 to deflect towards the substrate 15. Additionally, the articulation of the second end 40 of the cantilever beam 30 towards the substrate 15 may not depend on the wavelength of the laser beam 45.

The specific parameters, values, amounts, ranges, materials, types, brands, etc. described below are approximates and were merely selected for the experiments, and as such the embodiments herein are not limited to the specific descriptions below. An example of the fabrication process shown in FIGS. 2A through 2E begins with blanketing the NiTi (shape memory alloy 20) co-sputtered at 600° C. substrate temperature onto the Si substrate (wafer) 15. Ion milling through the film of NiTi (shape memory alloy 20) using a photo patterned layer of ˜2 μm thick AZ 5214e photoresist 22. With this pattern, the joule heater is etched on top of the Si substrate 15 with larger NiTi bond pads (200 μm squares) to eventually land contact probes. Another layer of the ˜2 μm thick AZ 5214e photoresist (not shown) is spin coated and developed to define exposed Si etch regions around the NiTi joule heater devices. This resist also masks off the bulk of the surface of the Si substrate 15 during the device release process, which comprises a xenon difluoride (XeF₂) etch to undercut the devices. On top of the NiTi (shape memory alloy 20), a 1 μm thick film of SU8 2000.5 negative photoresist (reflective coating 25) is spin coated. After photomask exposure and patterning, the SU8 (reflective coating 25) is the only remaining layer on top of the NiTi (shape memory alloy 20) and the NiTi bond pads (not shown) are exposed in order to facilitate experimental electrical characterizations. The SU8 (reflective coating 25) is spin coated at 4000 rpm and baked for 2 min at 95° C. and exposed with a contact aligner and mask plate at 160 mJ cm⁻². The complete SU8 2000.5 parameters used is detailed in Table 2.

TABLE 2
SU-8 2000.5 fabrication parameters
SU8 2000.5 fabrication

| | |
|---|---|
| Material | SU8 2000.5 |
| Spin speed (rpm) | 4000 |
| SU8 thickness (μm) | 1 |
| Soft Bake | 2 min @ 95° C. |
| Exposure | 160 mJ cm⁻² |
| Post exposure bake (PEB) | 4 min @ 95° C. |
| Develop | 50s in SU8 developer |
| Rinse | Fresh SU8 developer, IPA |

Upon release, the MEMS actuator device 10 curls upwards (FIG. 2D) due to the thermal expansion mismatch between the NiTi (shape memory alloy 20) and SU8 (reflective coating 25). In the austenite phase of film deposition, the CTE of NiTi is approximately 11 ppm ° C.⁻¹ compared to SU8 which is approximately 53 ppm ° C.⁻¹. The larger rate of contraction of the uppermost SU8 (reflective coating 25) would result in the stress profile the results in the upward curl shown in FIG. 2D.

The well-known Stoney's equation may be used to back out the NiTi residual stress based on measured film and wafer thicknesses and measured wafer curvature pre and post film deposition. The deflection of a bi-layer cantilever due to a temperature variation is expressed by the following equation, where the geometric parameters are those indicated in:

$$δ = {L}^{2} \frac{3 {( 1 + m )}^{2}}{t [ 3 {( m + 1 )}^{2} + ( 1 + mn ) ( {m}^{2} + \frac{1}{mn} ) ]} ( {α}_{2} - {α}_{1} ) ( ΔT ) .$$

In the above equation, α₁ and α₂ are the thermal expansion coefficients (CTE) of the bottom and top layer materials; n is the ratio of Young's modulus of NiTi and SU8 (Y₁/Y₂). m is the ratio of NiTi (shape memory alloy 20) and SU8 (reflective coating 25) thickness, t is the total cantilever thickness. The equation used to model radius of curvature is given as:

$$\frac{1}{R} = \frac{6 m}{{t ( m + 1 )}^{2}} ( {α}_{2} - {α}_{1} ) ( T - {T}_{0} ) .$$

where R is the radius of curvature and t, m, and a are the same as above.

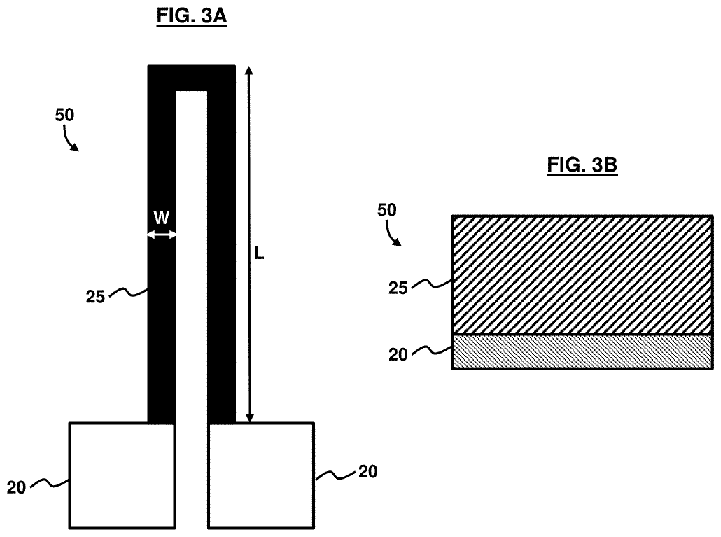

The configuration and cross-section of an example MEMS actuator device 10 is depicted in FIGS. 3A and 3B, with reference to FIGS. 1 through 2E. Example values of the length L=100, 150, 200, 300, and 400 μm. Example values of the width W=10, 15, and 20 μm. Example thickness of the layer of SU8 (reflective coating 25) is 1 μm. Example thickness of the layer of NiTi (shape memory alloy 20) is 270 nm. However, these values are only examples, and the embodiments herein are not restricted to these particular values.

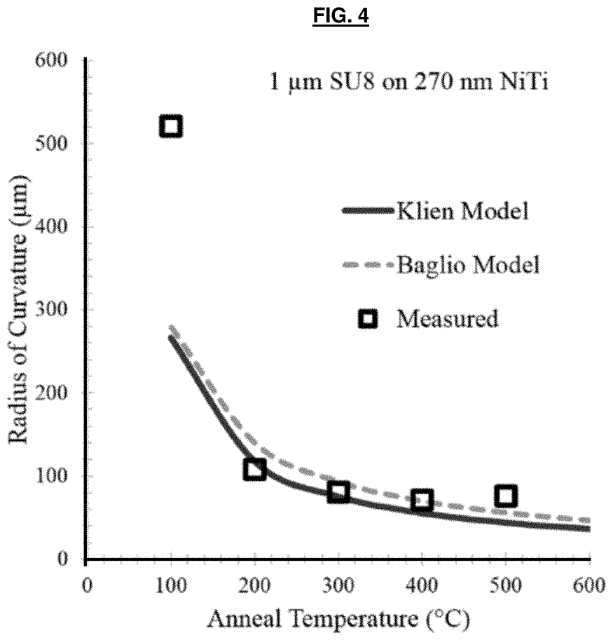

FIG. 4, with reference to FIGS. 1 through 3B, shows the measured radius of curvature of the released SU8 (reflective coating 25) on NiTi (shape memory alloy 20) as a function on SU8 post bake temperature. There is a clear dependence showing that hotter post bake temperature results in a beam with tighter curling radius once released from substrate. Moreover, the measured results generally follow the results from the well-known Klien and Baglio Models.

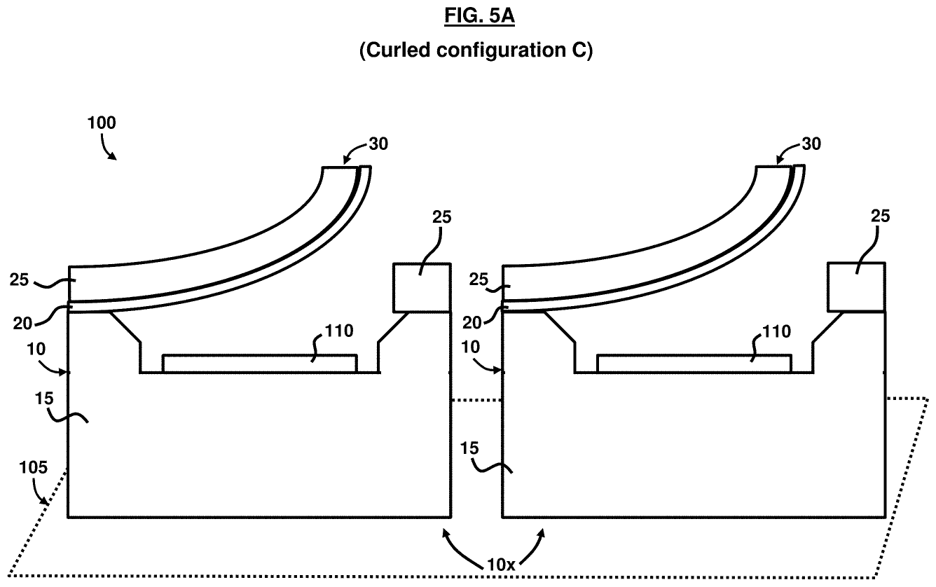

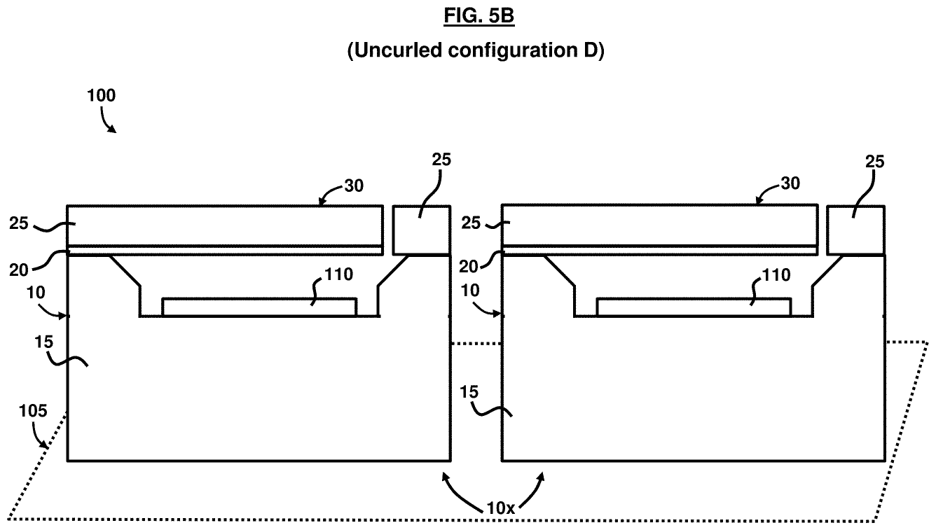

FIGS. 5A through 7 illustrate a micro shutter system 100. As shown in FIGS. 5A and 5B, with reference to FIGS. 1 through 4, the micro shutter system 100 comprises a plurality of MEMS actuator devices 10x arranged in a grid 105 and covering a sensor array 110, wherein each MEMS actuator device 10 comprises a substrate 15, a shape memory alloy 20 over the substrate 15, and a reflective coating 25 on the shape memory alloy 20. The shape memory alloy 20 and the reflective coating 25 form a cantilever beam 30. In an example, the reflective coating 25 may be at least three times thicker than the shape memory alloy 20. The cantilever beam 30 actuates between a curled configuration C away from the substrate 15 and a non-curled (e.g., uncurled) configuration D towards the substrate 15 when a temperature of the cantilever beam 30 reaches a phase change temperature of the shape memory alloy 20 causing a thermal phase change in the shape memory alloy 20. Each MEMS actuator device 10 of the plurality of MEMS actuator devices 10x independently actuates in response to being selectively heated.

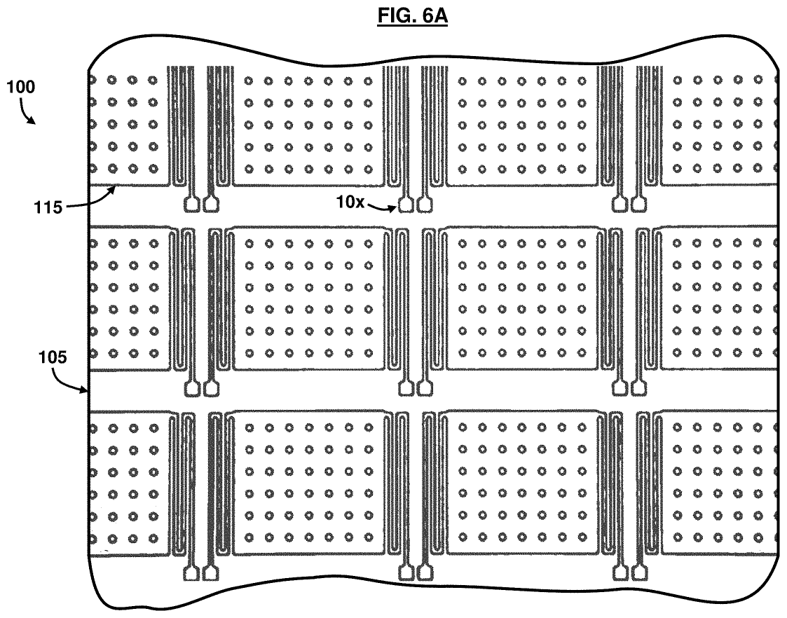

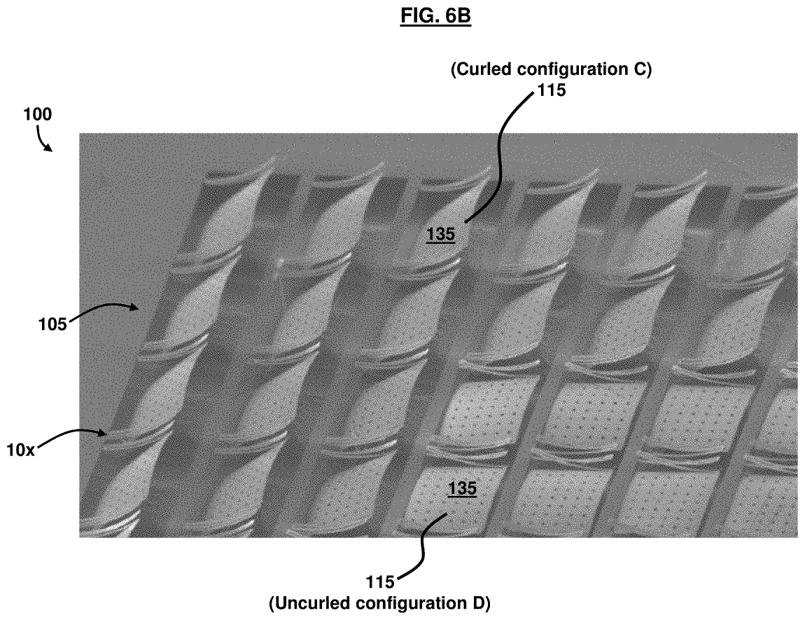

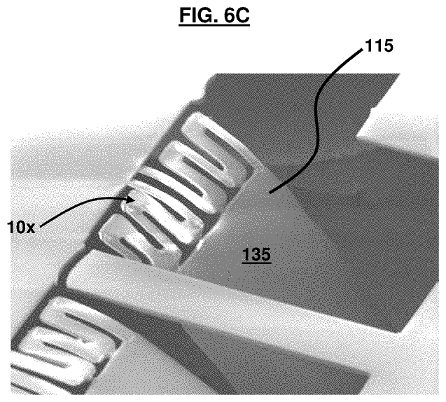

As shown in FIGS. 6A through 6C, with reference to FIGS. 1 through 5B, the micro shutter system 100 further comprises a rigid shutter 115 attached to each MEMS actuator device 10, wherein actuation of the cantilever beam 30 actuates the rigid shutter 115 over the sensor array 110. The independent actuation of each MEMS actuator device 10 of the plurality of MEMS actuator devices 10x in response to being selectively heated may result in at least one of the plurality of MEMS actuator devices 10x in the grid 105 being in the curled configuration C while remaining ones of the plurality of MEMS actuator devices 10x in the grid 105 being in the non-curled configuration D. The rigid shutter 115 may comprise a film 135 that is thermally or electrically biased to be infrared transmissive or infrared reflective. Each MEMS actuator device 10 may comprise a thermal expansion mismatch between the shape memory alloy 20 and the reflective coating 25. Moreover, each rigid shutter 115 in the grid 105 may independently actuate based on corresponding actuation of an attached MEMS actuator device 10.

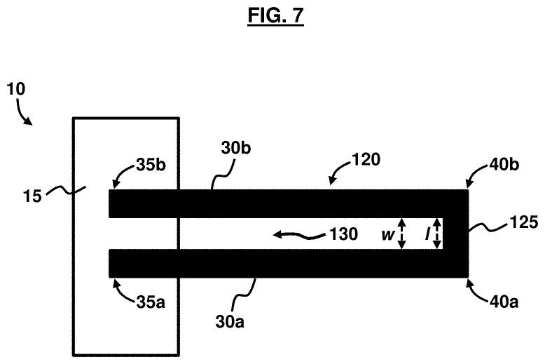

As shown in FIG. 7, with reference to FIGS. 1 through 6C, each MEMS actuator device 10 may comprise a bimorph actuator 120. The bimorph actuator 120 may comprise a first cantilever beam 30a comprising a first beam first end 35a anchored to the substrate 15, and a first beam second end 40a released from the substrate 15; a second cantilever beam 30b parallel to the first cantilever beam 30a, wherein the second cantilever beam 30b comprises a second beam first end 35b anchored to the substrate 15, and a second beam second end 40b released from the substrate 15; a lateral beam 125 connecting the first beam second end 40a to the second beam second end 40b; and a gap 130 between the first cantilever beam 30a and the second cantilever beam 30b, wherein a width w of the gap 130 is defined by a length/of the lateral beam 125.

Experiment

The specific parameters, values, amounts, ranges, materials, types, brands, etc. described below are approximates and were merely selected for the experiments, and as such the embodiments herein are not limited to the specific descriptions below. For the electrical actuation tests on joule heater devices such as the actuator devices 10x, a laser doppler vibrometry (LDV) is used to record cantilever displacement. The laser beam 45 may be focused 20 μm from the base of the cantilever beam 30 nearest the probe pads to measure the displacement at that point, which is then related to the radius of curvature using Euler-Bernoulli beam theory from which the displacement is derived. An arbitrary signal generator is integrated, capable to produce arbitrary voltage profiles (i.e. square, triangle, sinusoidal) to actuate the bimorph actuators 120.

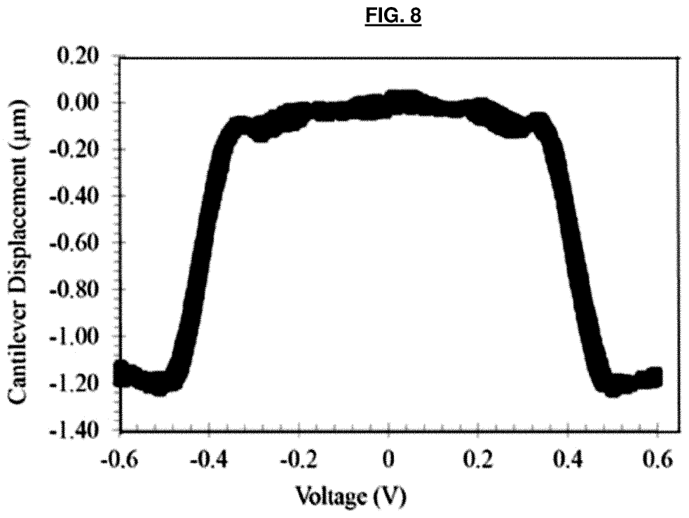

Experimentally, when actuated with a voltage input, the cantilever beam 30 deflects downward, hence the negative cantilever deflection. The maximum deflection appears to be 1.2 μm at the interrogation spot, which corresponded to a turn on voltage of 0.5 V. The SMA joule heater cantilever deflection is shown in FIG. 8, with reference to FIGS. 1 through 7, over a voltage sweep from −0.6 to 0.6 V, with an absolute turn on voltage of 0.5 V. This plot reveals the highly non-linear phase change between M-phase and A-phase. Using a curve fit to the bending beam, the bending radius is determined to be ˜100 μm at room temperature and ˜400 μm upon actuation, which corresponds to a radius change of ˜300 μm.

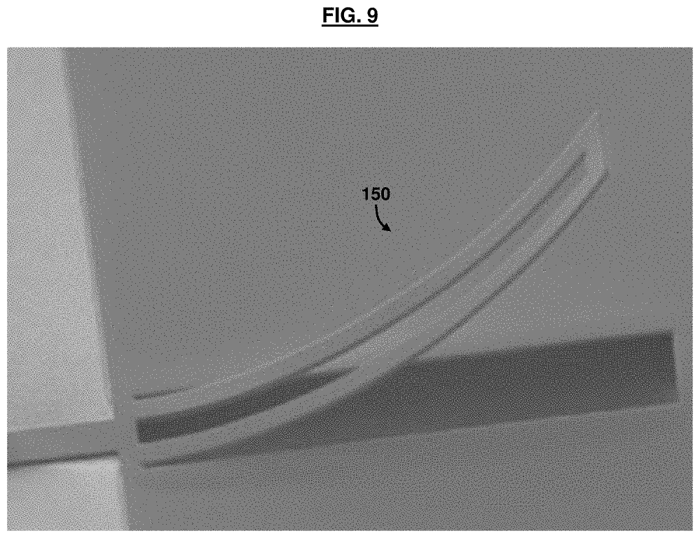

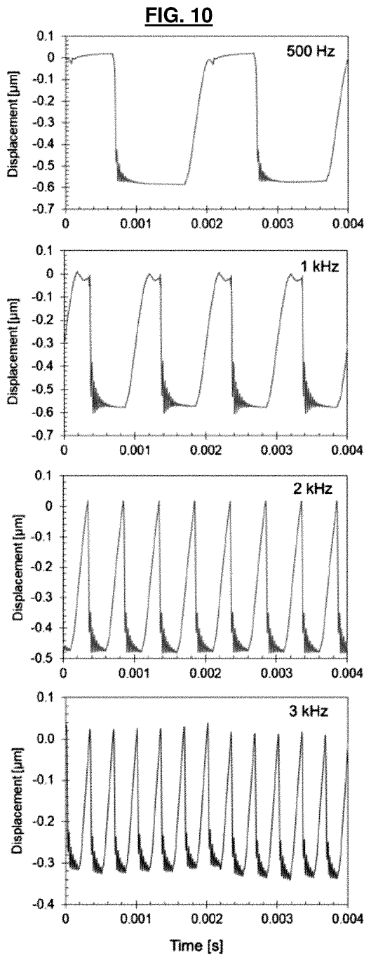

FIG. 9, with reference to FIGS. 1 through 8, shows SEM image of released joule heater beam 150. The beam 150 is clearly curled upwards. The device is also cycled, and recorded deflection data at 500 Hz, 1 kHz, and 2 kHz, and 3 kHz with a 1.0 V excitation, is shown in FIG. 10, with reference to FIGS. 1 through 9. At 500 Hz, and 1 kHz a mechanical ringing happens, and the device actuates to some maximum amount and flat lines for a period of time. At 2 kHz, the device deflection is recorded reversibly, but at a slightly diminished amplitude compared to the 0.5 and 1.0 Hz cases. Therefore, it is concluded that at ˜2 kHz (1/2000=0.5 milliseconds=500 μs), the device is crossing over into the regime where the heat cannot be removed from the device quickly enough to allow complete cool down. Further diminished, albeit reversible, deflection is also measured at 3 kHz rate, implying that partial heating and cooling is still happening at these time scales. This is supplemented with a thermal modeling which shows similar behavior on similar timescales (i.e. 490 μs heating thermal time constant (TTC), and 670 μs cooling TTC). At higher frequencies, the device does not reach the maximum deflection values. However, these results are able to indicate that partial heating and cooling could be achieved reversibly on these timescales at a reduced deflection amplitude. The response is not perfectly symmetric during a full actuation cycle due to the fact that the surface-controlled free convective cooling response is slower than that associated with the volumetric joule heating. At 1 kHz, a total displacement of 576 nm is measured after ring down.

The NiTi SMA actuators provided by the embodiments herein may be used to offer a lower voltage solution to the actuating and tuning problem with input as low as 0.5 V, and frequencies as high as 3 kHz. In order to determine the practical upper limit on actuation frequency, and confirm the experimental results above, ANSYS® modal analysis (available from Ansys, Inc., Pennsylvania, USA) and COMSOL® software transient thermal simulations may be performed. Simulating identical properties and geometries as the actual devices, ANSYS® modal analysis show that the first mechanical resonance is expected to vary between 9205 Hz and 10 045 Hz by changing the NiTi properties from the Martensite to Austenite phase. This result is much larger than the maximum verified operation condition of 2000 Hz, suggesting that these structures are not limited by mechanical resonance. COMSOL MULTIPHYSICS® software (available from Comsol AB, Stockholm, Sweden) may be used to simulate Joule heating of the devices. To determine the rate of Joule heating, the device resistance (which are summarized in Table 3) is determined by experimentally measuring I-V curves and fitting a line to determine R. Using this value of resistance, the thermal response of the actuators to a corresponding uniform volumetric Joule heating rate is simulated.

TABLE 3
Experimentally determined device resistance, R, for all five of the
device geometries considered

| | Resistance (ohms) | | |
|---|---|---|---|
| Length (μm) | 10 μm wide | 15 μm wide | 20 μm wide |
| 100 | 64.1 | 48.2 | 24.8 |
| 150 | 128.8 | 50.6 | 56.8 |
| 200 | 107.8 | 69.4 | 61.8 |
| 300 | 121.8 | 103.6 | 65.6 |
| 400 | 173.2 | 93.4 | 84.6 |

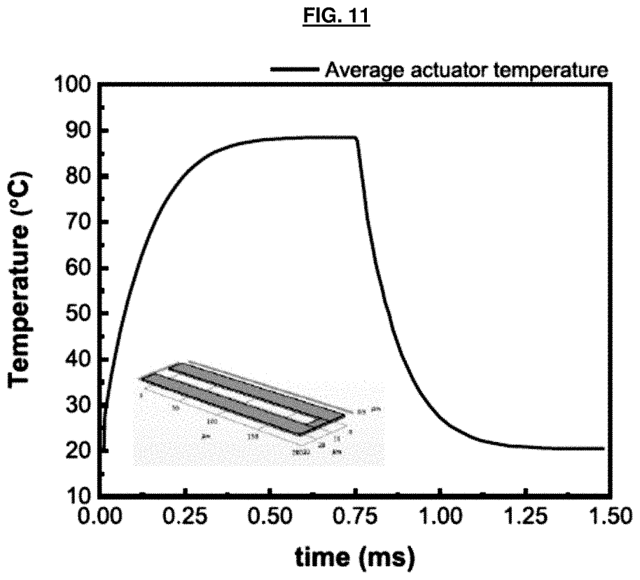

FIG. 11, with reference to FIGS. 1 through 10, shows the modeling of the heating up portion in martensite (M-phase), and the cooling down in Austenite (A-phase), assuming the following: 8.6 Wm⁻¹ K⁻¹ in M-phase, 18 Wm⁻¹ K⁻¹ in A-phase. The anchor points are fixed at 20° C., and the outer surfaces are cast with a convective coefficient of 3500 Wm⁻² K⁻¹, which is consistent with self-heated structures of similar size used in scanning thermal microscopy. The actuator starts at 20° C., and within 0.49 ms is within 0.5° C. of a steady-state temperature of ˜88.5° C. Then, Joule heating is turned off in the simulation and the actuator cools from ˜88.5° C. back down to within 0.5° C. of room temperature (20° C.) in 0.67 ms.

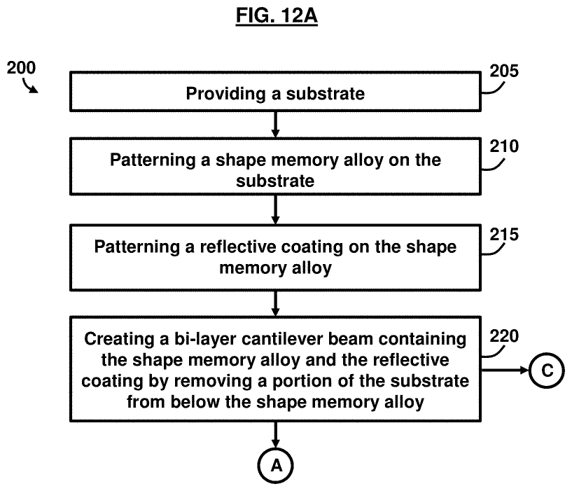

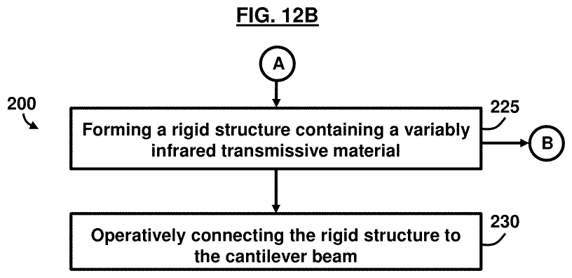

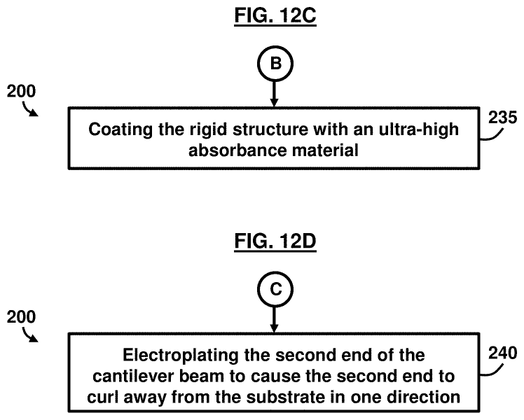

FIGS. 12A through 12D, with reference to FIGS. 1 through 11, is a flow diagram illustrating a method 200 of forming a MEMS actuator device 10. The method 200 comprises providing (205) a substrate 15. In an example, the substrate 15 comprises Si. Next, the method 200 comprises patterning (210) a shape memory alloy 20 on the substrate 15. According to an example, the shape memory alloy 20 may be formed of a NiTi-based alloy. Thereafter, the method 200 comprises patterning (215) a reflective coating 25 on the shape memory alloy 20. According to an example, the reflective coating 25 comprises SU8. After this, the method 200 comprises creating (220) a bi-layer cantilever beam 30 containing the shape memory alloy 20 and the reflective coating 25 by removing a portion of the substrate 15 from below the shape memory alloy 20. This may occur using conventional patterning techniques.

The cantilever beam 30 comprises a first end 35 and a distally located second end 40. The first end 35 of the cantilever beam 30 is anchored to the substrate 15, and the second end 40 of the cantilever beam 30 is released from the substrate 15. In an example, the second end 40 of the cantilever beam 30 curls away from the substrate 15, and the second end 40 of the cantilever beam 30 is configured to uncurl based on a thermal phase change in the shape memory alloy 20.

The method 200 may comprise forming (225) a rigid structure (e.g., rigid shutter 115 or other type of rigid structure) containing a variably infrared transmissive material, and operatively connecting (230) the rigid structure (e.g., rigid shutter 115 or other type of rigid structure) to a cantilever beam 30, wherein the rigid structure (e.g., rigid shutter 115 or other type of rigid structure) is configured to be deflected based on an actuation of the cantilever beam 30 from an uncurled configuration D to a curled configuration C.

The method 200 may comprise coating (235) the rigid structure (e.g., rigid shutter 115 or other type of rigid structure) with an ultra-high absorbance material, such as carbon black, titanium dioxide, or zinc oxide, according to some examples. Moreover, the method 200 may comprise electroplating (240) the second end 40 of the cantilever beam 30 to cause the second end 40 to curl away from the substrate 15 in one direction.

The MEMS actuator device 10 provided by the embodiments herein and based on NiTi SMA and may be used as an electrically actuated MEMS mirror, and could be used for laser beam steering, optical communication switching, i.e. routing optical signals on chip. Moreover, the MEMS actuator device 10 could be used for medical or commercial imaging technology. Further applications for the MEMS actuator device 10 include a MEMS thermal switch, circuit breaker, and laser actuated shutter.

Additionally, the micro shutter system 100 could be used for nonuniformity correction (NUC), which is typically accomplished via a camera sized shutter, that tends to be slow, and generally requires high power to electrically activate. NUC is commonly used by military personnel or end-users of a microbolometer based camera to maintain scene uniformity over time. In this embodiment, an array of micro shutters could be actuated with low power and provide the necessary uniform temperature to carry out periodic recalibration of the sensor array. Using the embodiments herein, by shrinking the device size, and having it intimately connected to Si wafer thermal heat sink, it is able to provide much faster reversible switching speeds due to rapid heat transfer that is physically impossible in much larger volumes. Experimentally, the heat may be transferred into and out of the MEMS actuator device 10 (electrical actuation) at up to over 1 kHz, or more than 1,000 times per second. The laser actuation also occurs on relatively rapid time scales and at relatively low laser irradiation intensity (W/cm²).

Another aspect of the embodiments herein is the relatively quick and easy processing. In one deposition step, the Nitinol (e.g. shape memory alloy 20) can be sputtered onto the Si substrate 15. As little as one or two additional photolithography and metal etch or deposition steps is utilized to make the functional MEMS actuator device 10, which can be biased into one position (harnessing residual stress in Cr, for example) and can be conformed to another position once heated beyond the phase change temperature.

The foregoing description of the specific embodiments will so fully reveal the general nature of the embodiments herein that others may, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein may be practiced with modification within the spirit and scope of the appended claims.

What is claimed is:

1. A microelectromechanical system (MEMS) actuator device comprising:
a substrate;
a shape memory alloy over the substrate; and
a reflective coating on the shape memory alloy,
wherein the shape memory alloy and the reflective coating form a bi-layer cantilever beam comprising a first end anchored to the substrate, and a second end released from the substrate, and
wherein the second end of the cantilever beam articulates between a deflection configuration away from the substrate and a non-deflection configuration towards the substrate based on a thermal phase change in the shape memory alloy.

2. The device of claim 1, wherein the second end of the cantilever beam articulates to the deflection configuration after being in the non-deflection configuration when the shape memory alloy is at a temperature below a phase change temperature of the shape memory alloy.

3. The device of claim 1, wherein an articulation of the second end of the cantilever beam between the deflection configuration and the non-deflection configuration comprises a frequency response up to 3,000 Hz.

4. The device of claim 3, wherein the articulation of the second end of the cantilever beam consumes approximately 1 mW of power.

5. The device of claim 1, wherein the cantilever beam is exposed to resistive heating to cause a temperature of the cantilever beam to reach a phase change temperature of the shape memory alloy to cause the second end of the cantilever beam to deflect towards the substrate.

6. The device of claim 1, wherein the cantilever beam is exposed to a laser beam to cause a temperature of the cantilever beam to reach a phase change temperature of the shape memory alloy to cause the second end of the cantilever beam to deflect towards the substrate.

7. The device of claim 6, wherein the articulation of the second end of the cantilever beam towards the substrate does not depend on the wavelength of the laser beam.

8. A micro shutter system comprising:
a plurality of microelectromechanical system (MEMS) actuator devices arranged in a grid and covering a sensor array, wherein each MEMS actuator device comprises:
a substrate;
a shape memory alloy over the substrate; and
a reflective coating on the shape memory alloy,
wherein the shape memory alloy and the reflective coating form a cantilever beam,
wherein the cantilever beam actuates between a curled configuration away from the substrate and a non-curled configuration towards the substrate when a temperature of the cantilever beam reaches a phase change temperature of the shape memory alloy causing a thermal phase change in the shape memory alloy, and
wherein each MEMS actuator device of the plurality of MEMS actuator devices independently actuates in response to being selectively heated; and
a rigid shutter attached to each MEMS actuator device, wherein actuation of the cantilever beam actuates the rigid shutter over the sensor array.

9. The system of claim 8, wherein each MEMS actuator device comprises a bimorph actuator.

10. The system of claim 9, wherein the bimorph actuator comprises:
a first cantilever beam comprising a first beam first end anchored to the substrate, and a first beam second end released from the substrate;
a second cantilever beam parallel to the first cantilever beam, wherein the second cantilever beam comprises a second beam first end anchored to the substrate, and a second beam second end released from the substrate;
a lateral beam connecting the first beam second end to the second beam second end; and
a gap between the first cantilever beam and the second cantilever beam, wherein a width of the gap is defined by a length of the lateral beam.

11. The system of claim 8, wherein the reflective coating is at least three times thicker than the shape memory alloy.

12. The system of claim 8, wherein independent actuation of each MEMS actuator device of the plurality of MEMS actuator devices in response to being selectively heated results in at least one of the plurality of MEMS actuator devices in the grid being in the curled configuration while remaining ones of the plurality of MEMS actuator devices in the grid being in the non-curled configuration.

13. The system of claim 8, wherein the rigid shutter comprises a film that is thermally or electrically biased to be infrared transmissive or infrared reflective.

14. The system of claim 8, wherein each MEMS actuator device comprises a thermal expansion mismatch between the shape memory alloy and the reflective coating.

15. The system of claim 8, wherein each rigid shutter in the grid independently actuates based on corresponding actuation of an attached MEMS actuator device.

16. A method of forming a microelectromechanical system (MEMS) actuator device, the method comprising:
providing a substrate;
patterning a shape memory alloy on the substrate;
patterning a reflective coating on the shape memory alloy; and
creating a bi-layer cantilever beam containing the shape memory alloy and the reflective coating by removing a portion of the substrate from below the shape memory alloy,
wherein a first end of the cantilever beam is anchored to the substrate, and a second end of the cantilever beam is released from the substrate,
wherein the second end of the cantilever beam curls away from the substrate, and
wherein the second end of the cantilever beam is configured to uncurl based on a thermal phase change in the shape memory alloy.

17. The method of claim 16, wherein the shape memory alloy is formed of a NiTi-based alloy.

18. The method of claim 16, comprising:
forming a rigid structure containing a variably infrared transmissive material; and
operatively connecting the rigid structure to the cantilever beam,
wherein the rigid structure is configured to be deflected based on an actuation of the cantilever beam from an uncurled configuration to a curled configuration.

19. The method of claim 18, comprising coating the rigid structure with an ultra-high absorbance material.

20. The method of claim 16, comprising electroplating the second end of the cantilever beam to cause the second end to curl away from the substrate in one direction.
